(19) United States
(12) Patent Application Publication
(10) Pub. No.: US 2026/0214976 A1
(43) Pub. Date: Jul. 23, 2026

(54) CONFORMAL SOURCE/DRAIN STRUCTURES FOR SEMICONDUCTOR DEVICES

(71) Applicant: Taiwan Semiconductor Manufacturing Company, Ltd., Hsinchu (TW)

(72) Inventors: Kuan-Hao Cheng, Hsinchu (TW); Wei-Yang Lee, Taipei City (TW); Bo-Yu Lai, Taipei City (TW)

(73) Assignee: Taiwan Semiconductor Manufacturing Company, Ltd., Hsinchu (TW)

(21) Appl. No.: 19/255,060

(22) Filed: Jun. 30, 2025

Related U.S. Application Data
(60) Provisional application No. 63/748,724, filed on Jan. 23, 2025.

(51) Int. Cl. H10D 84/83; H10D 30/00; H10D 30/01; H10D 30/43; H10D 30/47; H10D 62/10; H10D 62/13; H10D 64/27; H10D 64/66; H10D 84/01

(52) U.S. Cl. CPC H10D 84/832; H10D 30/014; H10D 30/0191; H10D 30/43; H10D 30/47; H10D 30/503; H10D 62/102; H10D 62/116; H10D 62/121; H10D 62/151; H10D 64/514; H10D 64/518; H10D 64/675; H10D 84/0147

(57) ABSTRACT

The present disclosure describes a semiconductor device having conformal source/drain structures in contact with convex inner spacers. The semiconductor device includes a channel structure on a substrate, a gate structure wrapped around the channel structure, a source/drain structure on the substrate and in contact with the channel structure, and an inner spacer between the gate structure and the S/D structure. A portion of the inner spacer extends into the source/drain structure.

### CROSS-REFERENCE TO RELATED APPLICATION

This application claims the benefit of U.S. Provisional Patent Application No. 63/748,724, titled “Nanosheet Strain for Semiconductor Devices,” filed Jan. 23, 2025, the disclosure of which is incorporated by reference in its entirety.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs and fin field effect transistors (FinFETs) ), gate-all-around field effect transistors (GAAFETs), complementary field effect transistors (CFETs), nanosheet transistors, nanowire transistors, multi-bridge channel transistors, nano-ribbon transistors, and other similar-structured transistors. Such scaling down has increased the complexity of semiconductor manufacturing processes and increased the difficulty of process and defect control in the semiconductor devices.

### BRIEF DESCRIPTION OF THE DRAWINGS

Aspects of the present disclosure are best understood from the following detailed description when read with the accompanying figures.

FIG. 1 illustrates an isometric view of a semiconductor device having conformal source/drain structures in contact with convex inner spacers, in accordance with some embodiments.

FIG. 2 illustrates a partial cross-sectional view of a semiconductor device having conformal source/drain structures in contact with convex inner spacers, in accordance with some embodiments.

FIG. 3 is a flow diagram of a method for fabricating a semiconductor device having conformal source/drain structures in contact with convex inner spacers, in accordance with some embodiments.

FIGS. 4-18 illustrate partial cross-sectional views of a semiconductor device having conformal source/drain structures in contact with convex inner spacers at various stages of its fabrication, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 20 % of the value (e.g., ±1 %, ±2 %, ±3 %, ±4 %, ±5 %, ±10 %, ±20 % of the value). These values are merely examples and are not intended to be limiting. The terms “about” and “substantially” can refer to a percentage of the values as interpreted by those skilled in relevant art(s) in light of the teachings herein.

With increasing demand for lower power consumption, higher performance, and smaller semiconductor devices, dimensions of semiconductor devices continue to scale down. The continuous scaling down of device dimensions and the increasing demand for device performance may require various process and material improvements, which can have multiple challenges. For example, a nanostructure transistor on a substrate can have a gate structure wrapped around a channel structure to improve device performance. The nanostructure transistor can have inner spacers to isolate the gate structure from source/drain (S/D) structures. A leakage current can flow between the S/D structures through the substrate below the channel structure. An isolation layer can be disposed between the S/D structures and the substrate to reduce the leakage current. Dislocation defects in the S/D structures can affect device performance of the nanostructure transistor. Conformal S/D structures in the present disclosure can reduce the dislocation defects and improve the device performance of the nanostructure transistor.

Various embodiments in the present disclosure provide methods for forming conformal S/D structures in contact with convex inner spacers in a semiconductor device (e.g., a nanostructure transistor) and/or other semiconductor devices in an integrated circuit (IC). In some embodiments, a semiconductor device can include a stack of nanostructures on a substrate. A gate structure can wrap around the stack of nanostructures. A S/D structure can be disposed adjacent to the gate structure and in contact with the stack of nanostructures. An inner spacer can be disposed between the gate structure and the S/D structure. An isolation layer can be disposed between the S/D structure and the substrate. In some embodiments, the inner spacer and the isolation layer can include the same dielectric material. In some embodiments, the inner spacer can have a convex surface extending into the S/D structure. In some embodiments, the S/D structure can be conformally formed on end portions of the stack of nanostructures. With the conformal S/D structure, the dislocation defects in the S/D structure can be reduced, resistance of the S/D structure can be reduced, and the device performance of the semiconductor device can be improved. Additionally, the isolation layer can reduce the leakage current of the semiconductor device and further improve the device performance. Moreover, the inner spacer and the isolation layer can be formed in the same process to reduce manufacturing cost.

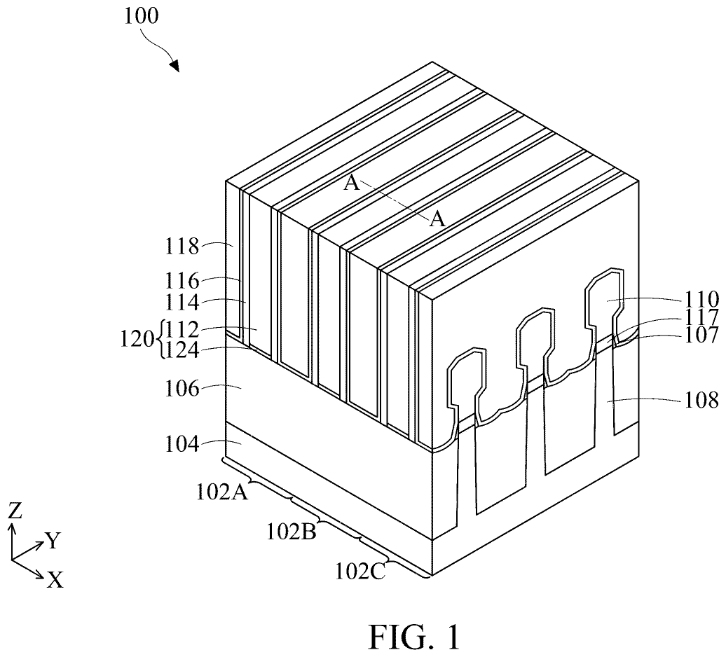

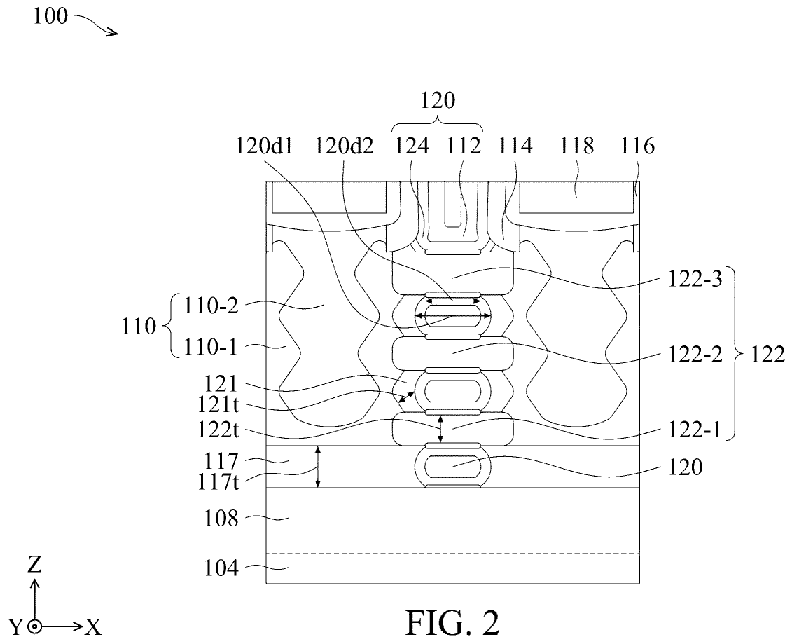

FIG. 1 illustrates an isometric view of a semiconductor device 100 having conformal source/drain structures in contact with convex inner spacers, in accordance with some embodiments. FIG. 2 illustrate a partial cross-sectional view of semiconductor device 100 across line A-A shown in FIG. 1, in accordance with some embodiments. In some embodiments, semiconductor device 100 can include transistors 102A-102C, as shown in FIG. 1. In some embodiments, transistors 102A-102C can include nanostructure transistors. The nanostructure transistors can include FinFETs, gate-all-around field effect transistors (GAA FETs), nanosheet transistors, nanowire transistors, multi-bridge channel transistors, nano-ribbon transistors, and other similar-structured transistors. The nanostructure transistors can provide a channel in a stacked nanosheet/nanowire configuration.

In some embodiments, transistors 102A-102C can be n-type field-effect transistors (NFETs). In some embodiments, transistors 102A-102C can be p-type field-effect transistors (PFETs). In some embodiments, any of transistors 102A-102C can be an NFET or a PFET. Though FIG. 1 shows three transistors, semiconductor device 100 can have any number of transistors. In addition, semiconductor device 100 can be incorporated into an IC through the use of other structural components, such as conductive vias, conductive lines, dielectric layers, passivation layers, and interconnects, which are not shown for simplicity. The discussion of elements of transistors 102A-102C with the same annotations applies to each other, unless mentioned otherwise. And like reference numerals generally indicate identical, functionally similar, and/or structurally similar elements.

Referring to FIGS. 1 and 2, semiconductor device 100 having transistors 102A-102C can be formed on a substrate 104 and can be isolated by shallow trench isolation (STI) regions 106. Each of transistors 102A-102C can include fin structures 108, bottom isolation layer 117, nanostructures 122-1, 122-2, and 122-3 (collectively referred to as “nanostructures 122”), sidewall spacers 107, gate structures 120, gate spacers 114, inner spacers 121, S/D structures 110, etch stop layer (ESL) 116, and interlayer dielectric (ILD) layer 118.

Referring to FIGS. 1 and 2, substrate 104 can include a semiconductor material, such as silicon. In some embodiments, substrate 104 includes a crystalline silicon substrate (e.g., wafer). In some embodiments, substrate 104 includes (i) an elementary semiconductor, such as germanium; (ii) a compound semiconductor including silicon carbide, gallium arsenide, gallium phosphide, indium phosphide, indium arsenide, and/or indium antimonide; (iii) an alloy semiconductor including silicon germanium carbide, silicon germanium, gallium arsenic phosphide, and/or aluminum gallium arsenide; or (iv) a combination thereof. Further, substrate 104 can be doped depending on design requirements (e.g., p-type substrate or n-type substrate). In some embodiments, substrate 104 can be doped with p-type dopants (e.g., boron, indium, aluminum, or gallium) or n-type dopants (e.g., phosphorus or arsenic).

STI regions 106 can provide electrical isolation between transistors 102A-102C and from neighboring transistors (not shown) on substrate 104 and/or neighboring active and passive elements (not shown) integrated with or deposited on substrate 104. STI regions 106 can be made of a dielectric material. In some embodiments, STI regions 106 can include silicon oxide, silicon nitride, silicon oxynitride, fluorine-doped silicate glass (FSG), a low-k dielectric material, and/or other suitable insulating materials. In some embodiments, STI regions 106 can include a multi-layered structure.

Referring to FIGS. 1 and 2, nanostructures 122 and fin structures 108 can be formed on patterned portions of substrate 104. Embodiments of the nanostructures and fin structures disclosed herein may be patterned by any suitable method. For example, the nanostructures and fin structures may be patterned using one or more photolithography processes, including double-patterning or multi-patterning processes. Double-patterning or multi-patterning processes can combine photolithography and self-aligned processes, forming patterns that have, for example, pitches smaller than what is otherwise obtainable using a single, direct photolithography process. For example, a sacrificial layer is formed over a substrate and patterned using a photolithography process. Spacers can be formed alongside the patterned sacrificial layer using a self-aligned process. The sacrificial layer is then removed, and the remaining spacers can then be used to pattern the nanostructures and fin structures.

As shown in FIGS. 1 and 2, nanostructures 122 and fin structures 108 can extend along an X-axis for transistors 102A-102C. In some embodiments, nanostructures 122 and fin structures 108 can be disposed on substrate 104. Nanostructures 122 can include a set of nanostructures 122-1, 122-2, and 122-3, which can be in the form of semiconductor layers, nanosheets, nanowires, or nano-ribbons. Each of nanostructures 122 can act as a channel structure and can form a channel region underlying gate structures 120 of transistors 102A-102C.

In some embodiments, nanostructures 122 and fin structures 108 can include semiconductor materials similar to or different from substrate 104. In some embodiments, nanostructures 122 and fin structures 108 can include silicon. The semiconductor materials of nanostructures 122 and fin structures 108 can be undoped or can be in-situ doped during their formation process. In some embodiments, as shown in FIG. 2, nanostructures 122 under gate structures 120 can form channel regions of semiconductor device 100 and represent current carrying channel structures of semiconductor device 100. In some embodiments, as shown in FIG. 2, nanostructures 122 can have a thickness 122t along a Z-axis ranging from about 3 nm to about 15 nm. Though three layers of nanostructures 122 are shown in FIG. 2, transistors 102A-102C can have any number of nanostructures 122.

Referring to FIGS. 1 and 2, gate structures 120 can include gate dielectric layer 124 and gate electrode 112. In some embodiments, gate dielectric layer 124 can be formed on nanostructures 122, fin structures 108, and STI regions 106. In some embodiments, gate dielectric layer 124 can be multi-layered structures and can include an interfacial layer and a high-k dielectric layer. In some embodiments, a high-k dielectric layer can be in direct contact with nanostructures 122. In some embodiments, the interfacial layer can include silicon oxide formed by a deposition process or an oxidation process. In some embodiments, the interfacial layer can have a thickness ranging from about 0.1 nm to about 1.5 nm. In some embodiments, the high-k dielectric layer can include hafnium oxide, zirconium oxide, or other suitable high-k dielectric materials.

In some embodiments, as shown in FIGS. 1 and 2, gate electrode 112 can be disposed on gate dielectric layer 124. In some embodiments, gate electrode 112 can include one or more work function metal layers and a metal fill. The one or more work function metal layers can include work function metals to tune the threshold voltage (Vₜ) of transistors 102A-102C. In some embodiments, gate electrode 112 for NFET and PFET devices can have the same work-function metal. In some embodiments, gate electrode 112 for NFET and PFET devices can have different work-function metals. In some embodiments, as shown in FIG. 2, each of nanostructures 122 can be wrapped around by gate structures 120, for which gate structures 120 can be referred to as “gate-all-around (GAA) structures” and transistors 102A-102C can also be referred to as “GAA FETs 102A-102C.” The one or more work function metal layers can wrap around nanostructures 122 and can include work function metals to tune the Vₜ of transistors 102A-102C. In some embodiments, transistors 102A-102C can include any number of work function metal layers for Vₜ tuning (e.g., ultra-low Vₜ, low Vₜ, and standard Vₜ).

In some embodiments, NFETs 102A-102C can include n-type work function metal layers. The n-type work function metal layers can include aluminum, titanium aluminum, titanium aluminum carbon, tantalum aluminum, tantalum aluminum carbon, tantalum silicon carbide, hafnium carbide, silicon, titanium nitride, titanium silicon nitride, or other suitable work function metals. In some embodiments, PFETs 102A-102C can include p-type work function metal layers. The p-type work function metal layers can include titanium nitride, titanium silicon nitride, tantalum nitride, tungsten carbon nitride, tungsten, molybdenum, or other suitable work function metals. In some embodiments, the work function metal layers can include a single metal layer or a stack of metal layers. The stack of metal layers can include work function metals having work-function values equal to or different from each other. In some embodiments, the metal fill can include titanium, tantalum, aluminum, cobalt, tungsten, nickel, ruthenium, or other suitable conductive materials.

In some embodiments, as shown in FIG. 2, gate structures 120 between nanostructures 122 can have an ellipse profile in contact with a concave surface of inner spacers 121. In some embodiments, as shown in FIG. 2, center regions of gate structures 120 can have a length 120d1 along an X-axis ranging from about 10 nm to about 20 nm. In some embodiments, as shown in FIG. 2, edge regions of gate structures 120 can have a length 120d2 along an X-axis ranging from about 10 nm to about 15 nm. In some embodiments, length 120d1 of the center regions can be greater than length 120d2 of the edge regions of gate structures 120. In some embodiments, a difference between 120d1 and 120d2 can range from about 2 nm to about 5 nm. In some embodiments, a ratio of length 120d1 to length 120d2 can range from about 1.1 to about 1.5. If the difference is less than about 2 nm or the ratio is less than about 1.1, inner spacers 121 may not have a convex surface extending into conformal S/D structures 110 and dislocation defects in S/D structures 110 may increase. If the difference is greater than about 5 nm or the ratio is greater than about 1.5, gate control of the device current in nanostructures 122 by gate structures 120 may be reduced.

Referring to FIGS. 1 and 2, gate spacers 114 can be disposed on sidewalls of gate structures 120 and sidewall spacers 107 can be disposed on sidewalls of fin structures 108. Gate spacers 114 and sidewall spacers 107 can include insulating materials, such as silicon oxide, silicon nitride, silicon oxynitride, silicon carbonitride, silicon oxycarbide, silicon oxycarbonitride, a low-k material, and a combination thereof. In some embodiments, gate spacers 114 and sidewall spacers 107 can include the same insulating material. In some embodiments, gate spacers 114 and sidewall spacers 107 can include different insulating materials. In some embodiments, gate spacers 114 and sidewall spacers 107 can include a single layer or a stack of insulating layers. In some embodiments, gate spacers 114 and sidewall spacers 107 can include a low-k material with a dielectric constant less than about 3.9 (e.g., about 3.5, about 3.0, or about 2.8).

In some embodiments, S/D structures 110 can be disposed between adjacent stacks of nanostructures 122 and on opposing sides of gate structures 120. In some embodiments, S/D structures 110 can be disposed on a top surface of bottom isolation layer 117. In some embodiments, S/D structures 110 can be in contact with nanostructures 122 and inner spacers 121. S/D structures 110 can function as S/D regions of transistors 102A-102C. In some embodiments, S/D structures 110 can have any geometric shape, such as a polygon, an ellipse, and a circle. In some embodiments, S/D structures 110 can include an epitaxially-grown semiconductor material, such as silicon (e.g., the same material as substrate 104). In some embodiments, the epitaxially-grown semiconductor material can include an epitaxially-grown semiconductor material different from the material of substrate 104, such as silicon germanium, and imparts a strain on the channel regions under gate structures 120. Since the lattice constant of such epitaxially-grown semiconductor material is different from the material of substrate 104, the channel regions are strained to increase carrier mobility in the channel regions of semiconductor device 100. The epitaxially-grown semiconductor material can include: (i) a semiconductor material, such as germanium and silicon; (ii) a compound semiconductor material, such as gallium arsenide and aluminum gallium arsenide; or (iii) a semiconductor alloy, such as silicon germanium and gallium arsenide phosphide. In some embodiments, S/D structures 110 grown on nanostructures 122 can be conformal and the dislocation defects in S/D structures 110 can be reduced. With reduced dislocation defects, the strain imparted on the channel regions by S/D structures 110 can increase, the resistance of S/D structures 110 can be reduced, and the device performance of semiconductor device 100 can be improved.

In some embodiments, S/D structures 110 can include silicon and can be in-situ doped during an epitaxial growth process using n-type dopants, such as phosphorus and arsenic. In some embodiments, S/D structures 110 can include silicon, silicon germanium, germanium, or III-V materials (e.g., indium antimonide, gallium antimonide, or indium gallium antimonide) and can be in-situ doped during an epitaxial growth process using p-type dopants, such as boron, indium, and gallium. In some embodiments, S/D structures 110 can include one or more epitaxial layers, where each epitaxial layer can have different compositions. For example, as shown in FIG. 2, S/D structures 110 can include first epitaxial layer 110-1 and second epitaxial layer 110-2. In some embodiments, first epitaxial layer 110-1 and second epitaxial layer 110-2 can be conformal and can have reduced dislocation defects. In some embodiments, first epitaxial layer 110-1 can include silicon germanium with a germanium concentration from about 10 % to about 50 %. In some embodiments, second epitaxial layer 110-2 can include silicon germanium with a germanium concentration from about 50 % to about 100 %. In some embodiments, first epitaxial layer 110-1 can include silicon doped with an n-type dopant at a first concentration. In some embodiments, second epitaxial layer 110-2 can include silicon doped with an n-type dopant at a second concentration greater than the first concentration. In some embodiments, S/D structures 110 can have a width along an X-axis ranging from about 20 nm to about 40 nm. In some embodiments, S/D structures 110 can have a height along a Z-axis ranging from about 50 nm to about 100 nm.

In some embodiments, as shown in FIG. 2, first epitaxial layer 110-1 can be in contact with inner spacers 121 and bottom isolation layer 117. In some embodiments, first epitaxial layer 110-1 can include a boron doped silicon layer or a silicon germanium layer with a lower germanium concentration from about 10 % to about 20 %. The boron doped silicon layer and the silicon germanium layer with the lower germanium concentration can be in contact with inner spacers 121 and bottom isolation layer 117. In some embodiments, the boron doped silicon layer and the silicon germanium layer with the lower germanium concentration can act as an etch stop layer. In some embodiments, the boron doped silicon layer and the silicon germanium layer with the lower germanium concentration can protect S/D structures 110 during the formation of inner spacers 121 and bottom isolation layer 117.

In some embodiments, inner spacers 121 can be disposed between gate structures 120 and S/D structures 110. In some embodiments, inner spacers 121 can include dielectric materials, such as silicon oxide, silicon nitride, silicon oxynitride, silicon carbonitride, silicon oxycarbide, silicon oxycarbonitride, a low-k material, and a combination thereof. In some embodiments, as shown in FIG. 2, inner spacers 121 can have a convex surface extending into S/D structures 110. In some embodiments, as shown in FIG. 2, inner spacers 121 can have a concave surface in contact with gate structures 120 having an ellipse profile. In some embodiments, inner spacers 121 can be conformal on S/D structures 110 and can have a thickness 121t ranging from about 3 nm to about 7 nm. In some embodiments, a ratio of thickness 121t to thickness 122t can range from about 0.2 to about 0.8. If thickness 121t is less than about 3 nm or the ratio is less than about 0.2, gate structures 120 may be short to S/D structures 110. If thickness 121t is greater than about 7 nm or the ratio is greater than about 0.8, gate structures 120 may not fill between nanostructures 122 and may not wrap around nanostructures 122.

In some embodiments, as shown in FIG. 2, bottom isolation layer 117 can be disposed on fin structures 108/substrate 104 and in contact with gate structures 120. In some embodiments, bottom isolation layer 117 can be disposed between S/D structures 110 and fin structures 108/substrate 104. In some embodiments, as shown in FIG. 2, bottom surfaces of gate structures 120 and bottom isolation layer 117 can be substantially on the same level. In some embodiments, as shown in FIG. 2, a top surface of bottom isolation layer 117 can be below a bottom surface of bottom nanostructure 122-1. In some embodiments, bottom isolation layer 117 can include insulating materials, such as silicon oxide, silicon nitride, silicon oxynitride, silicon carbonitride, silicon oxycarbide, silicon oxycarbonitride, a low-k material, and a combination thereof. In some embodiments, bottom isolation layer 117 and inner spacers 121 can include the same dielectric material. In some embodiments, a top surface of bottom isolation layer 117 can be below a bottom surface of bottom nanostructure 122-1. In some embodiments, bottom isolation layer 117 can have a thickness 117t ranging from about 3 nm to about 7 nm. In some embodiments, a ratio of thickness 117t to thickness 122t can range from about 0.2 to about 0.8. If thickness 117t is less than about 3 nm or the ratio is less than about 0.2, bottom isolation layer 117 may not isolate S/D structures 110 from substrate 104. If thickness 117t is greater than about 7 nm or the ratio is greater than about 0.8, gate structures 120 may not fill between nanostructures 122 and may not wrap around nanostructures 122.

Referring to FIGS. 1 and 2, ESL 116 can be disposed on STI regions 106, S/D structures 110, and sidewalls of gate spacers 114 and sidewall spacers 107. ESL 116 can be configured to protect STI regions 106, S/D structures 110, and gate structures 120 during the formation of S/D contact structures on S/D structures 110. In some embodiments, ESL 116 can include, for example, silicon oxide, silicon nitride, silicon oxynitride, silicon carbide, silicon carbonitride, boron nitride, silicon boron nitride, silicon carbon boron nitride, or a combination thereof.

ILD layer 118 can be disposed on ESL 116 over S/D structures 110 and STI regions 106. ILD layer 118 can include a dielectric material deposited using a deposition method suitable for flowable dielectric materials. For example, flowable silicon oxide can be deposited using flowable chemical vapor deposition (FCVD). In some embodiments, the dielectric material can include silicon oxide.

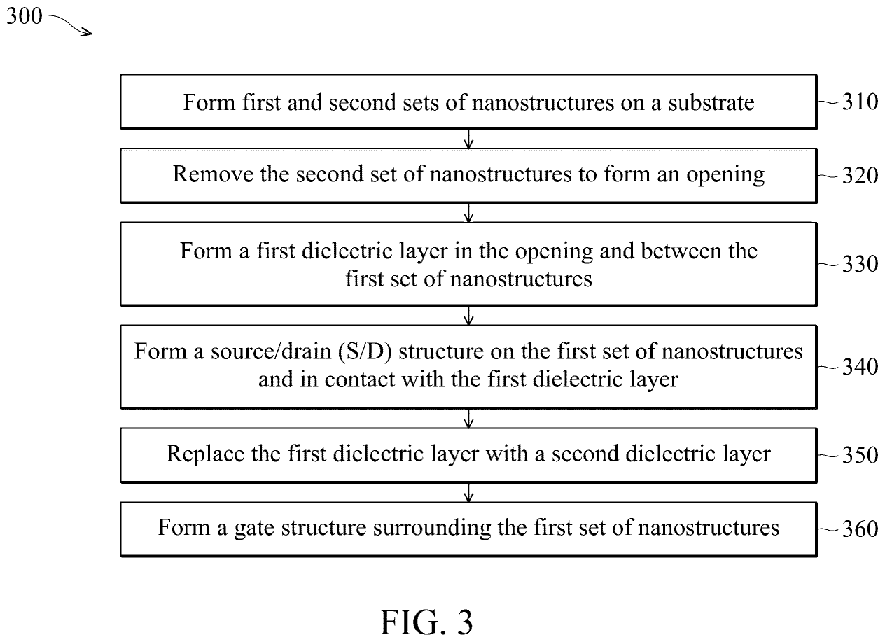

FIG. 3 is a flow diagram of a method 300 for fabricating semiconductor device 100 having conformal source/drain structures in contact with convex inner spacers, in accordance with some embodiments. Method 300 may not be limited to nanostructure transistor devices and can be applicable to other devices that would benefit from the conformal source/drain structures in contact with convex inner spacers. Additional fabrication operations may be performed between various operations of method 300 and may be omitted merely for clarity and ease of description. Additional processes can be provided before, during, and/or after method 300; one or more of these additional processes are briefly described herein. Moreover, not all operations may be needed to perform the disclosure provided herein. Additionally, some of the operations may be performed simultaneously or in a different order than shown in FIG. 3. In some embodiments, one or more other operations may be performed in addition to or in place of the presently-described operations.

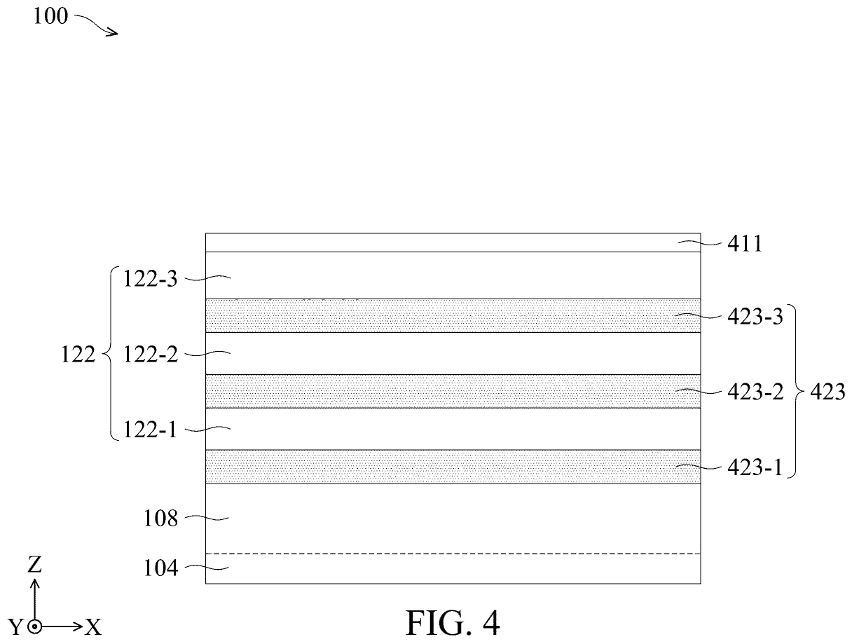

For illustrative purposes, the operations illustrated in FIG. 3 will be described with reference to the example fabrication process for fabricating semiconductor device 100 as illustrated in FIGS. 4-18. FIGS. 4-18 illustrate partial cross-sectional views of semiconductor device 100 having conformal source/drain structures in contact with convex inner spacers at various stages of its fabrication, in accordance with some embodiments. In some embodiments, Elements in FIGS. 4-18 with the same annotations as elements in FIGS. 1 and 2 are described above.

In referring to FIG. 3, method 300 begins with operation 310 and the process of forming first and second sets of nanostructures on a substrate. For example, as shown in FIG. 4, first set of nanostructures 122 and second set of nanostructures 423-1, 423-2, and 423-3 (collectively referred to as “nanostructures 423”) can be formed on substrate 104. In some embodiments, the formation of first and second sets of nanostructures 122 and 423 can include the deposition of first and second sets of semiconductor layers followed by a patterning process. In some embodiments, the first and second sets of semiconductor layers can be epitaxially grown on substrate 104. Embodiments of fin structures 108 and nanostructures 122 and 423 disclosed herein may be patterned by any suitable method. For example, the fin structures and the nanostructures may be patterned using one or more photolithography processes, including double-patterning or multi-patterning processes. Double-patterning or multi-patterning processes can combine photolithography and self-aligned processes, forming patterns that have, for example, pitches smaller than what is otherwise obtainable using a single, direct photolithography process. For example, a sacrificial layer is formed over a substrate and patterned using a photolithography process. Spacers can be formed alongside the patterned sacrificial layer using a self-aligned process. The sacrificial layer is then removed, and the remaining spacers can then be used to pattern the fin structures and the nanostructures. In some embodiments, as shown in FIG. 4, first and second sets of nanostructures 122 and 423 can be stacked in an alternate configuration. In some embodiments, nanostructures 122 and 423 can be in the form of semiconductor layers, nanosheets, nanowires, or nano-ribbons.

In some embodiments, fin structures 108 can include the same semiconductor material as substrate 104. In some embodiments, nanostructures 122 and 423 can include different semiconductor materials. In some embodiments, nanostructures 122 can include silicon. In some embodiments, nanostructures 423 can include silicon germanium with a germanium concentration ranging from about 20 % to about 60 %. In some embodiments, each of nanostructures 122 can have a thickness along a Z-axis ranging from about 3 nm to about 15 nm. In some embodiments, each of nanostructures 423 can have a thickness along a Z-axis ranging from about 5 nm to about 15 nm. In some embodiments, as shown in FIG. 4, a capping layer 411 can be formed on the stack of nanostructures 122 and 423. In some embodiments, capping layer 411 can include a dielectric material such as silicon oxide to protect the stack of nanostructures 122 and 423. In some embodiments, capping layer 411 can have a thickness ranging from about 1 nm to about 3 nm.

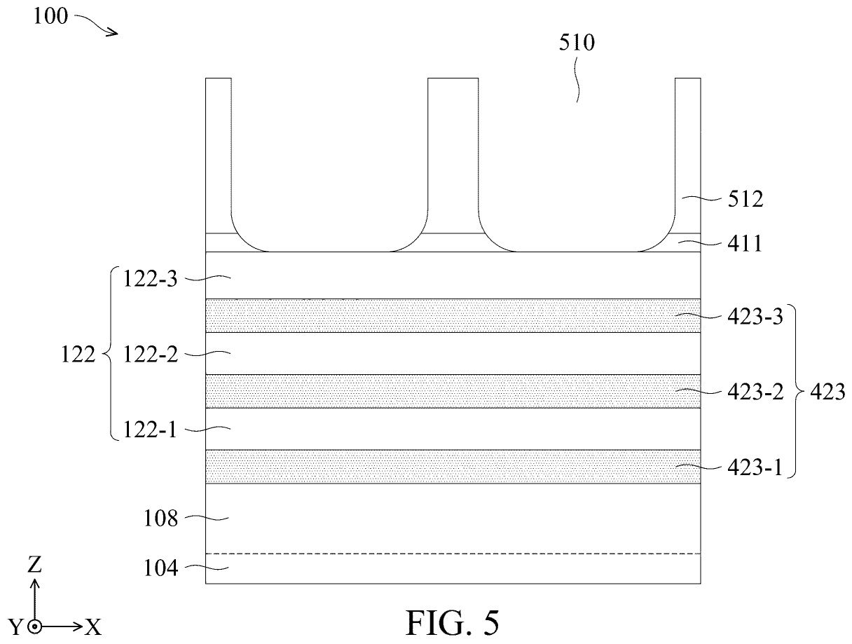

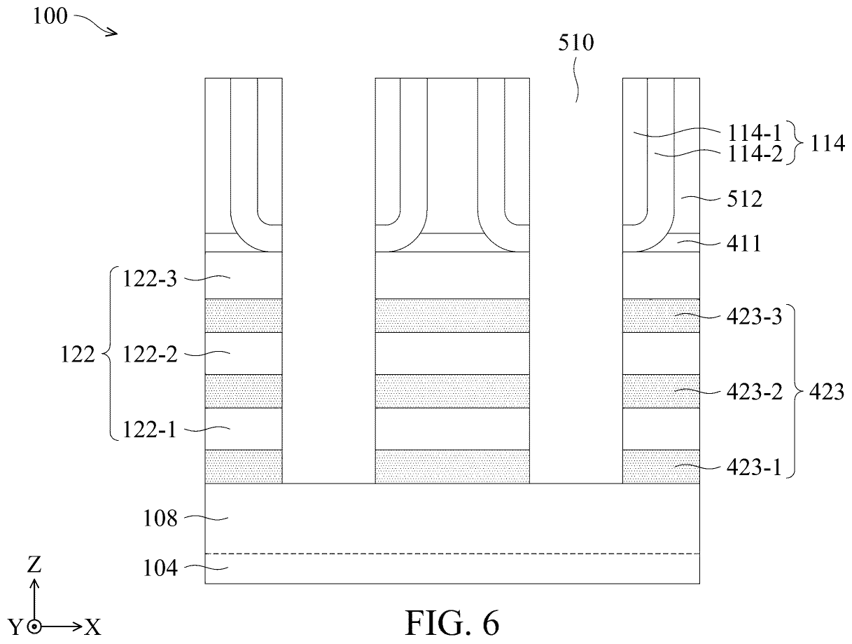

The formation of nanostructures 122 and 423 can be followed by the formation of sacrificial gate structures 512 on nanostructures 122 followed by a patterning process, the formation of gate spacers 114 on sidewalls of sacrificial gate structures 512, and the recess of nanostructures 122 and 423 to form openings 510, as shown in FIGS. 5 and 6.

In some embodiments, sacrificial gate structures 512 can include polysilicon. In some embodiments, gate spacers 114 can include insulating materials, such as silicon oxide, silicon nitride, silicon oxynitride, silicon carbonitride, silicon oxycarbide, silicon oxycarbonitride, a low-k material, and a combination thereof. In some embodiments, gate spacers 114 can include multi layers, such as first spacer layer 114-1 and second spacer layer 114-2 shown in FIG. 6. In some embodiments, first spacer layer 114-1 and second spacer layer 114-2 can include different insulating materials.

In some embodiments, as shown in FIG. 6, nanostructures 122 and 423 can be vertically recessed on both sides of sacrificial gate structures 512 to form openings 510. In some embodiments, the vertical recess of nanostructures 122 and 423 can include a directional etching process. In some embodiments, the directional etching process can remove nanostructures 122 and 423 on both sides of sacrificial gate structures 512. In some embodiments, the directional etching process can expose fin structures 108 to ensure complete removal of nanostructures 423 on fin structures 108.

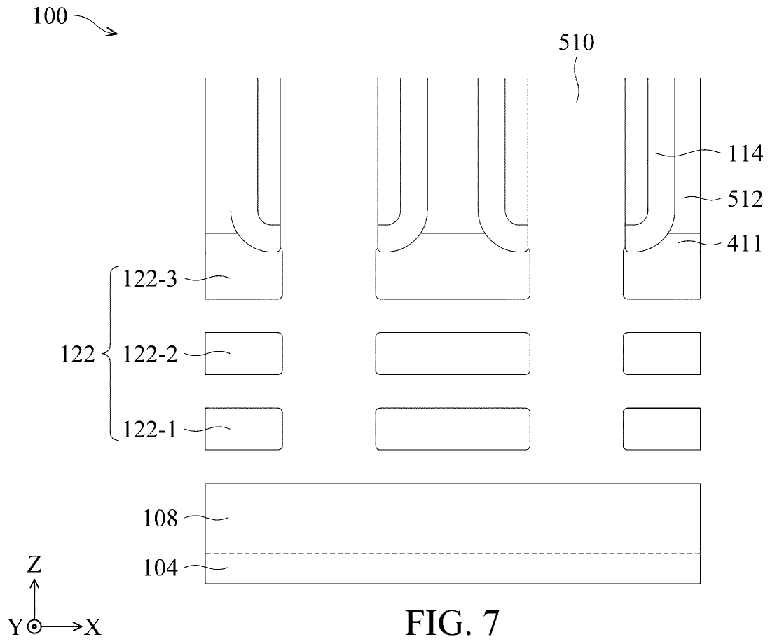

Referring to FIG. 3, in operation 320, the second set of nanostructures are removed to form an opening. For example, as shown in FIG. 7, second set of nanostructures 423 can be laterally removed through openings 510 to form openings 510 between nanostructures 122 and on both sides of sacrificial gate structures 512. In some embodiments, nanostructures 423 can be removed by a selective etching process. In some embodiments, the selective etching process can use etchants having different selectivity between nanostructures 122 and nanostructures 423. In some embodiments, the selective etching process can completely remove nanostructures 423 without the removal of nanostructures 122, gate spacers 114, or sacrificial gate structures 512. In some embodiments, the selective etching process can laterally extend openings 510 between nanostructures 423.

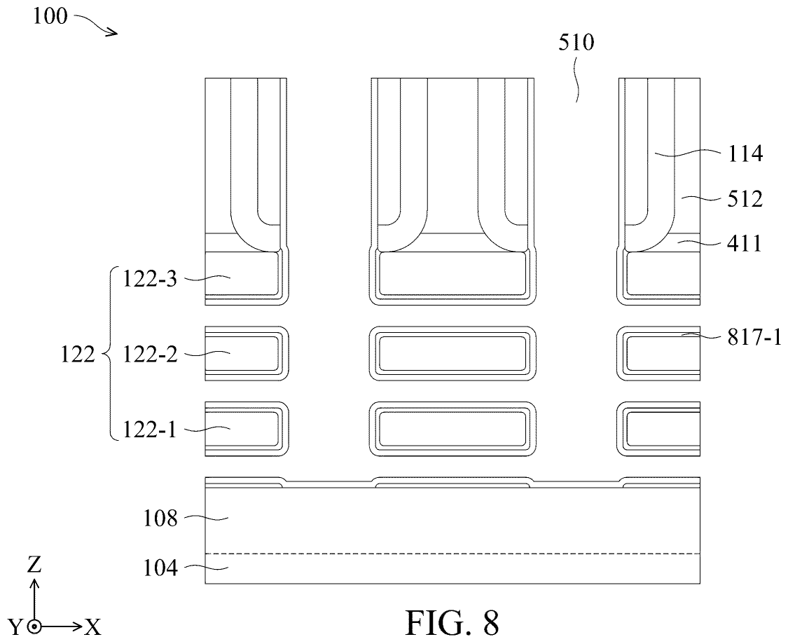

Referring to FIG. 3, in operation 330, first dielectric layer is formed in the opening and between the first set of nanostructures. For example, as shown in FIGS. 8-10, first dielectric layer 817 can be formed in openings 510 and between first set of nanostructures 122. In some embodiments, the formation of first dielectric layer 817 can include the deposition of first dielectric sublayer 817-1, the deposition of second dielectric sublayer 817-2, and the lateral recess of the first dielectric layer 817.

In some embodiments, as shown in FIG. 8, first dielectric sublayer 817-1 can be conformally deposited on nanostructures 122, fin structures 108, and gate spacers 114. In some embodiments, first dielectric sublayer 817-1 can be deposited by atomic layer deposition (ALD) or other suitable conformal deposition methods. In some embodiments, first dielectric sublayer 817-1 can be deposited at a temperature ranging from about 50° C. to about 390° C. In some embodiments, the deposition process can performed for about 1 to about 10 cycles using precursors including elements of carbon, hydrogen, nitrogen, and silicon. In some embodiments, first dielectric sublayer 817-1 can include a dielectric material, such as silicon oxide. In some embodiments, first dielectric sublayer 817-1 can have a thickness ranging from about 0.5 nm to about 1.5 nm.

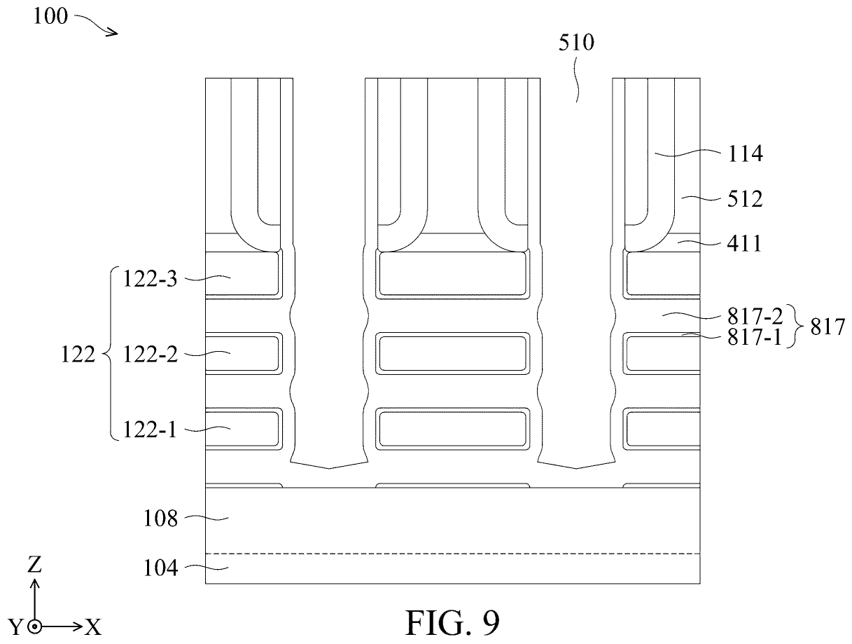

In some embodiments, as shown in FIG. 9, second dielectric sublayer 817-2 can fill openings 510 between nanostructures 122. In some embodiments, second dielectric sublayer 817-2 can be deposited on first dielectric sublayer 817-1 by flowable chemical vapor deposition (FCVD) or other suitable deposition methods. FCVD can deposit a flowable dielectric material that conforms and flows into narrow trenches and gaps before it cures and solidifies. Accordingly, FCVD can fill high-aspect-ratio gaps void free with a higher throughput than ALD. In some embodiments, FCVD can have a better gap fill capability than ALD to fill openings 510 between nanostructures 122 without voids. In some embodiments, second dielectric sublayer can be deposited around nanostructures 122 and on fin structures 108 to fill openings 510 between nanostructures 122 as well as between bottom nanostructures 122-1 and fin structures 108, as shown in FIG. 9. In some embodiments, second dielectric sublayer 817-2 can be deposited at a temperature ranging from about 50° C. to about 200° C. In some embodiments, the deposition process can use precursors including trisilylamine (TSA) and ammonia (NH₃). In some embodiments, second dielectric sublayer 817-2 can include a dielectric material such as silicon oxide. In some embodiments, first and second dielectric sublayers 817-1 and 817-2 can include the same dielectric material deposited with different deposition methods. In some embodiments, second dielectric sublayer 817-2 can have a thickness ranging from about 3 nm to about 15 nm.

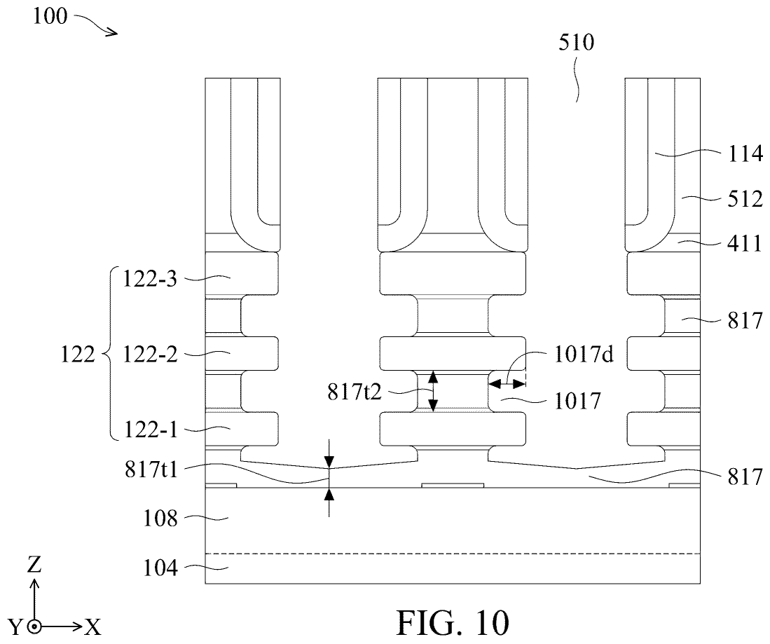

In some embodiments, as shown in FIG. 10, first dielectric layer 817 can be laterally etched to form recess 1017 between nanostructures 122. In some embodiments, the lateral recess can be performed by a dry etching process. In some embodiments, the lateral recess can be performed by a selective etching process. In some embodiments, the selective etching process can remove first dielectric layer 817 on gate spacers 114 and end portions of nanostructures 122. In some embodiments, the selective etching process can expose the end portions of nanostructures 122. In some embodiments, the selective etching process can remove first dielectric layer 817 between end portions of nanostructures 122 to form recess 1017. In some embodiments, recess 1017 can have a depth 1017d along an X-axis ranging from about 5 nm to about 10 nm. In some embodiments, recess 1017 can provide space for the subsequent conformal growth of S/D structures 110 on nanostructures 122. In some embodiments, the selective etching process can remove a portion of first dielectric layer 817 on fin structures 108 and, after the selective etching process, first dielectric layer 817 can remain on fin structures 108. In some embodiments, after the selective etching process, recess 1017 can also be formed between bottom nanostructure 122-1 and first dielectric layer 817 on fin structures 108, as shown in FIG. 10.

In some embodiments, as a portion of first dielectric layer 817 on fin structures 108 in openings 510 is removed during the selective etching process, a thickness of first dielectric layer 817 on fin structures 108 can be less than a thickness of first dielectric layer between nanostructures 122 as well as between bottom nanostructure 122-1 and fin structures 108. In some embodiments, first dielectric layer 817 on fin structures 108 can have a thickness 817t1 along a Z-axis ranging from about 3 nm to about 7 nm. In some embodiments, first dielectric layer 817 between nanostructures 122, as well as between bottom nanostructure 122-1 and fin structures 108, can have a thickness 817t2 along a Z-axis ranging from about 5 nm to about 15 nm. In some embodiments, a ratio of thickness 817t1 to thickness 817t2 can range from about 0.2 to about 0.7. If the ratio is less than about 0.2 or 817t1 is less than about 3 nm, subsequently-formed bottom isolation layer may not reduce the leakage current of semiconductor device 100. If the ratio is greater than about 0.7 or thickness 817t2 is less than about 5 nm, gate structures 120 may not be formed between nanostructures 122.

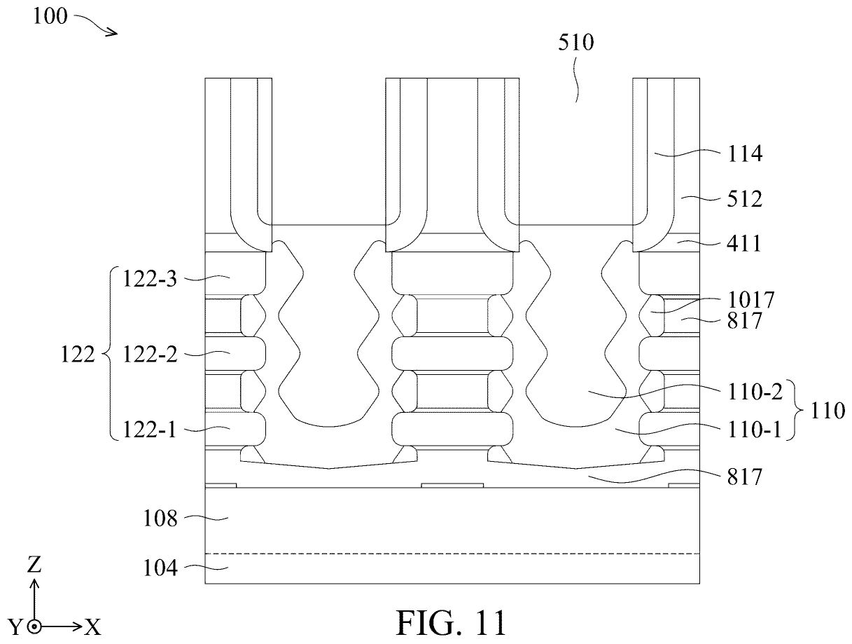

Referring to FIG. 3, in operation 340, S/D structures 110 is formed on the first set of nanostructures and in contact with the first dielectric layer. For example, as shown in FIG. 11, S/D structures 110 can be formed on first set of nanostructures 122 and in contact with first dielectric layer 817. In some embodiments, S/D structures 110 can be epitaxially grown on the end portions of nanostructures 122. In some embodiments, as shown in FIG. 11, S/D structures 110 can include first epitaxial layer 110-1 and second epitaxial layer 110-2. In some embodiments, with recess 1017 between the end portions of nanostructures 122, first epitaxial layer 110-1 can be conformally grown on nanostructures 122. In some embodiments, second epitaxial layer 110-2 can be conformally grown on conformal first epitaxial layer 110-1. In some embodiments, first epitaxial layer 110-1 can include silicon germanium with a germanium concentration from about 10 % to about 50 %. In some embodiments, second epitaxial layer 110-2 can include silicon germanium with a germanium concentration from about 50 % to about 100%. In some embodiments, conformally grown S/D structures 110 can be in contact with first dielectric layer 817 on fin structures 108. In some embodiments, as shown in FIG. 11, conformally grown S/D structures 110 can form a concave surface adjacent to recess 1017. In some embodiments, as shown in FIG. 11, a top surface of S/D structures 110 can be above a bottom surface of gate spacers 114.

In some embodiments, S/D structures 110 can include an epitaxially-grown semiconductor material different from the material of nanostructures 122 and substrate 104, such as silicon germanium or silicon, and can impart a strain on the channel regions of nanostructures 122. Since the lattice constant of such epitaxially-grown semiconductor material is different from the material of nanostructures 122, the channel regions are strained to increase carrier mobility in the channel regions of semiconductor device 100. In some embodiments, S/D structures 110 grown on nanostructures 122 adjacent to recess 1017 can be conformal and the dislocation defects in S/D structures 110 can be reduced. With reduced dislocation defects, the strain imparted on the channel regions by S/D structures 110 can increase, the resistance of S/D structures 110 can be reduced, and the device performance of semiconductor device 100 can be improved.

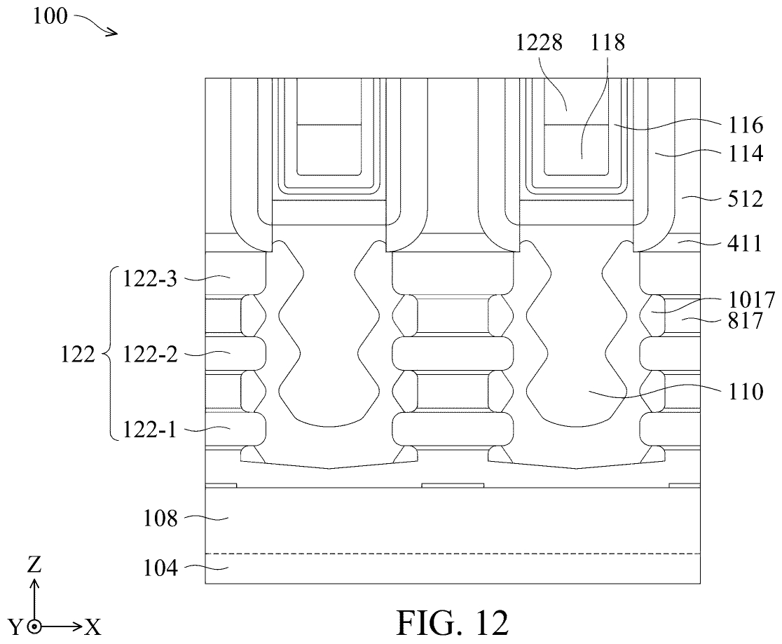

In some embodiments, the formation of S/D structures 110 can be followed by the formation of ESL 116, ILD layer 118 and hard mask layer 1228, as shown in FIG. 12. In some embodiments, ESL 116 can be deposited on S/D structures 110 and sidewalls of gate spacers 114 to protect S/D structures 110. In some embodiments, ILD layer 118 can be deposited on ESL 116 over S/D structures 110. In some embodiments, hard mask layer 1228 can be deposited on ILD layer 118 to protect ILD layer 118 and S/D structures 110 during subsequent removal of sacrificial gate structures 512. In some embodiments, hard mask layer 1228 can include silicon nitride. In some embodiments, the deposition of hard mask layer 1228 can be followed by a chemical mechanical planarization (CMP) process to planarize top surfaces of hard mask layer 1228, ESL 116, gate spacers 114, and sacrificial gate structures 512, as shown in FIG. 12.

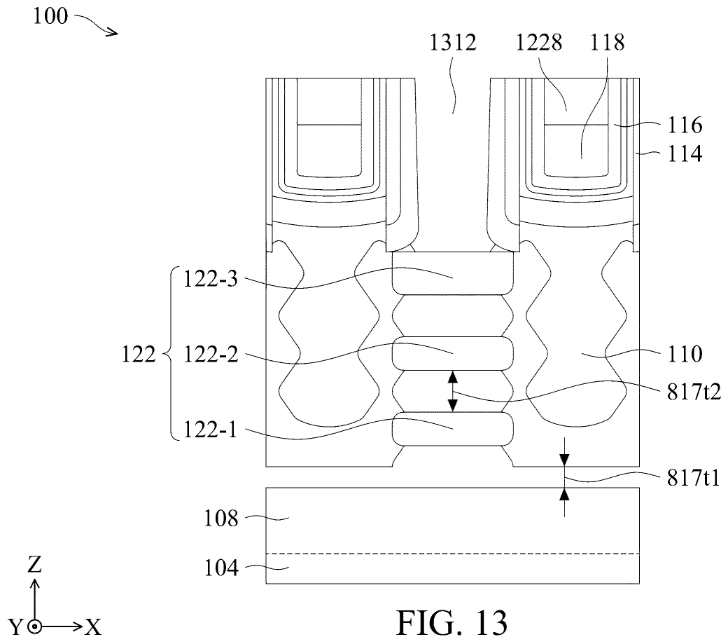

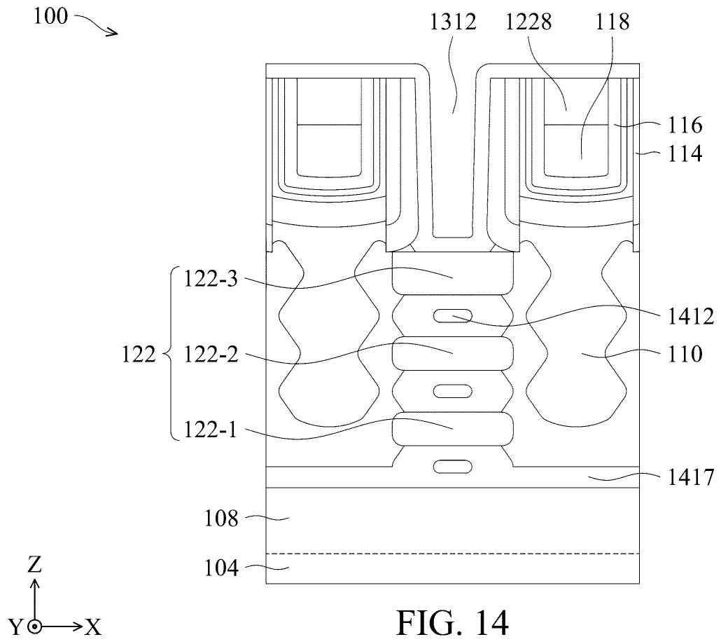

Referring to FIG. 3, in operation 350, the first dielectric layer is replaced with a second dielectric layer. For example, as shown in FIGS. 13 and 14, first dielectric layer 817 is replaced with a second dielectric layer 1417. In some embodiments, the replacement of first dielectric layer 817 with second dielectric layer 1417 can include the removal of sacrificial gate structures 512 and first dielectric layer 817, the deposition of second dielectric layer 1417, and the removal of a portion of second dielectric layer 1417.

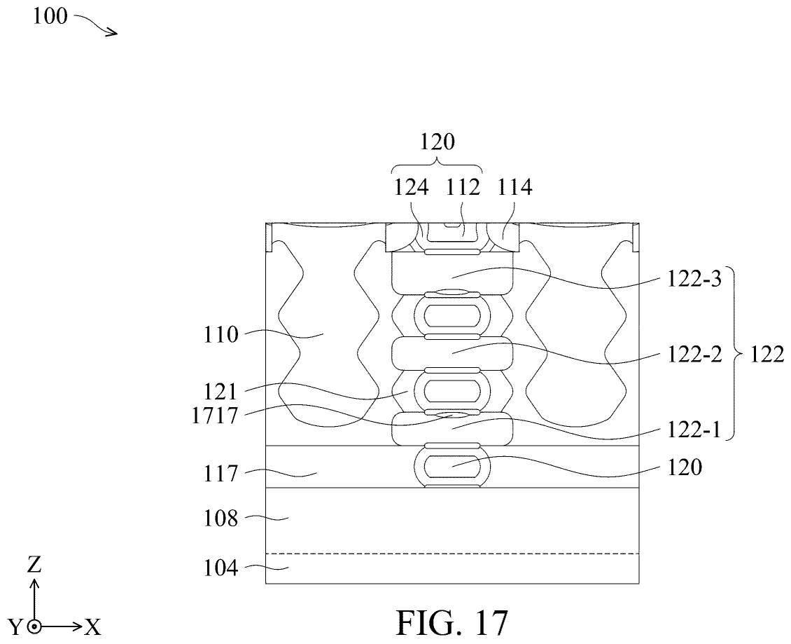

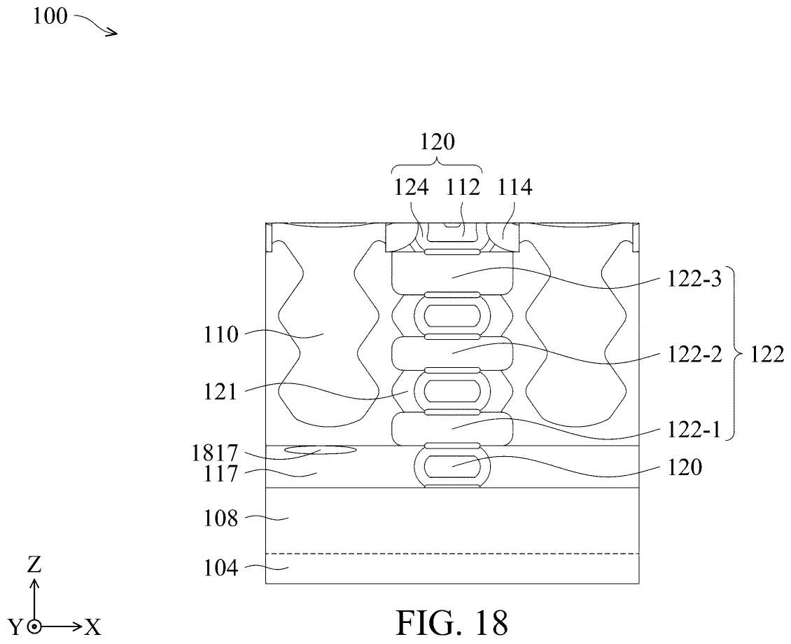

In some embodiments, as shown in FIG. 13, sacrificial gate structures 512 and first dielectric layer 817 can be removed by a wet etching process or a dry etching process. In some embodiments sacrificial gate structures 512 and first dielectric layer 817 can be removed by one etching process or a series of etching processes. In some embodiments, the wet or dry etching process can remove first dielectric layer 817 between nanostructures 122 and first dielectric layer 817 between S/D structures 110 and fin structures 108. In some embodiments, after the wet or dry etching process, a portion of first dielectric layer 817 can remain on nanostructures 122 and/or on S/D structures 110, as shown below in FIGS. 17 and 18. In some embodiments, after the wet or dry etching process, opening 1312 can be formed between nanostructures 122 and between S/D structures 110 and fin structures 108. In some embodiments, as shown in FIG. 13, after removal of first dielectric layer 1312, opening 1312 can have a first spacing between S/D structures 110 and fin structures 108 equal to thickness 817t1 and a second spacing between nanostructures 122 equal to thickness 817t2. As thickness 817t1 is less than thickness 817t2, the first spacing can be less than the second spacing. In some embodiments, after removal of first dielectric layer 817 between nanostructures 122, the concave surface of S/D structures 110 between nanostructures 122 can be exposed.

In some embodiments, as shown in FIG. 14, second dielectric layer 1417 can be conformally deposited on gate spacers 114 and in opening 1312. In some embodiments, second dielectric layer 1417 can be conformally deposited by ALD, CVD or other suitable deposition methods. In some embodiments, second dielectric layer 1417 can fill opening 1312 between S/D structures 110 and fin structures 108. In some embodiments, second dielectric layer 1417 can be conformally deposited on nanostructures 122, fin structures 108, and the concave surface of S/D structures 110 between nanostructures 122. In some embodiments, second dielectric layer 1417 can include dielectric materials, such as silicon oxide, silicon nitride, silicon oxynitride, silicon carbonitride, silicon oxycarbide, silicon oxycarbonitride, a low-k material, and a combination thereof. In some embodiments, as discussed above, the first spacing between S/D structures 110 and fin structures 108 can be less than the second spacing between nanostructures 122. As a result, after the deposition process, second dielectric layer 1417 can fill the first spacing while second dielectric layer 1417 can have voids 1412 surrounded by second dielectric layer 1417 in the second spacing, as shown in FIG. 14. In some embodiments, as shown in FIG. 14, second dielectric layer 1417 can have a convex surface in contact with the concave surface of S/D structures 110. In some embodiments, second dielectric layer 1417 can have voids 1412 between nanostructures 122. In some embodiments, voids 1412 and opening 1312 can be connected. In some embodiments, voids 1412 can have a width along an X-axis ranging from about 1 nm to about 3 nm.

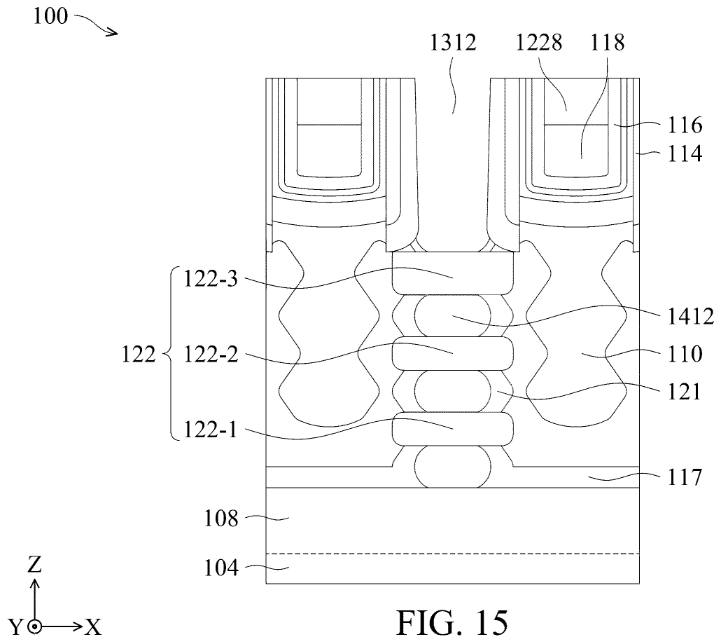

In some embodiments, as shown in FIG. 15, a portion of second dielectric layer 1417 can be removed. In some embodiment, the portion of second dielectric layer 1417 can be removed by a wet etching process. In some embodiments, the wet etching process can include an etchant such as phosphoric acid (H₃PO₄). In some embodiments, the wet etching process can remove second dielectric layer 1417 from gate spacers 114 and nanostructures 122. In some embodiments, the wet etching process can remove second dielectric layer 1417 on nanostructures 122 through opening 1312 and voids 1412. In some embodiments, the wet etching process can expose nanostructures 122 for subsequent formation of gate structures 120. In some embodiments, after the wet etching process, inner spacers 121 can be conformally formed on the concave surface of S/D structures 110 and voids 1412 can be enlarged to expose nanostructures 122. In some embodiments, inner spacers 121 can have a convex surface in contact with the concave surface of S/D structures 110. In some embodiments, the convex surface of inner spacers 121 can extend into S/D structures 110. In some embodiments, because second dielectric layer 1417 can fill the first spacing between S/D structures 110 and fin structures 108, after the wet etching process, second dielectric layer 1417 between S/D structures 110 and fin structures 108 may not be removed and can form bottom isolation layer 117 between S/D structures 110 and fin structures 108. In some embodiments, as shown in FIG. 15, bottom isolation layer 117 can be disposed between S/D structures 110 and fin structures 108/substrate 104. In some embodiments, as method 300 can form inner spacers 121 after the formation of S/D structures 110, method 300 can be referred to as an “inner spacer last” process. In some embodiments, as inner spacers 121 and bottom isolation layer 117 can be formed in the same process, manufacturing cost can be reduced.

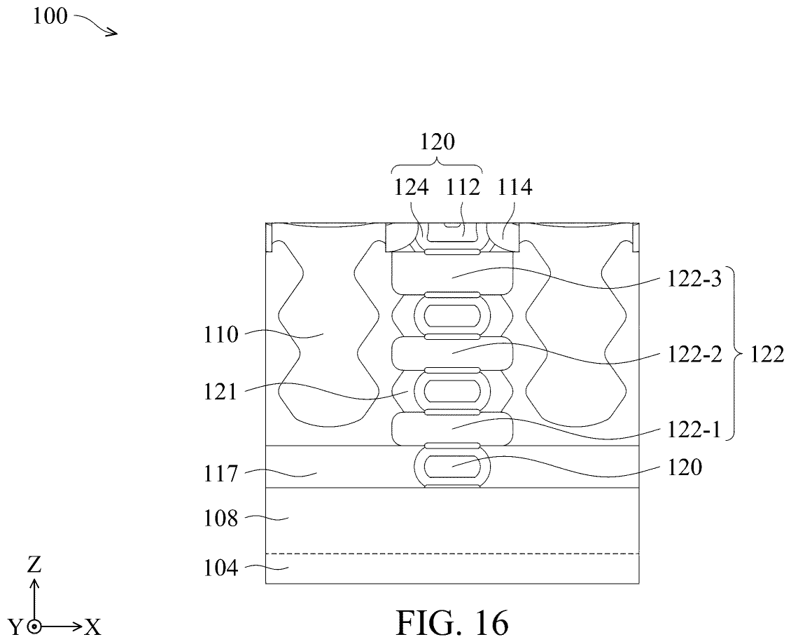

Referring to FIG. 3, in operation 360, a gate structure can be formed surrounding the first set of nanostructures. For example, as shown in FIG. 16, gate structures 120 can be formed surrounding first set of nanostructures 122. In some embodiments, the formation of gate structures 120 can include the formation of gate dielectric layer 124 and gate electrode 112. In some embodiments, as shown in FIG. 16, gate dielectric layer 124 can be formed on nanostructures 122 and fin structures 108. In some embodiments, gate dielectric layer 124 can be multi-layered structures and can include an interfacial layer and a high-k dielectric layer. In some embodiments, the interfacial layer can include silicon oxide formed by a deposition process or an oxidation process. In some embodiments, the high-k dielectric layer can include hafnium oxide, zirconium oxide, or other suitable high-k dielectric materials. In some embodiments, gate electrode 112 can be deposited on gate dielectric layer 124. In some embodiments, the deposition of gate electrode 112 can include deposition of one or more work function metal layers and deposition of a metal fill. These processes are not described in detail for clarity.

In some embodiments, as shown in FIG. 16, gate structures 120 between nanostructures 122 can have an ellipse profile because of the convex surface of inner spacers 121 extending into S/D structures 110. In some embodiments, gate structures 120 can be in contact with a concave surface of inner spacers 121. In some embodiments, gate structures 120 can be in contact with bottom isolation layer 117. In some embodiments, as shown in FIG. 16, bottom surfaces of gate structures 120 and bottom isolation layer 117 can be substantially on the same level. In some embodiments, as shown in FIG. 16, a top surface of bottom isolation layer 117 can be below a bottom surface of bottom nanostructure 122-1. In some embodiments, the formation of gate structures 120 can be followed by a CMP process to planarize top surfaces of gate structures 120, gate spacers 114, ESL 116, and ILD layer 118.

In some embodiments, as shown in FIG. 17, a portion of first dielectric layer 817 on nanostructures 122 may remain after the removal process of first dielectric layer 817 in operation 350 to form dielectric structures 1717. In some embodiments, dielectric structures 1717 and first dielectric layer 817 can include the same dielectric material. In some embodiments, gate structures 120 can be formed on nanostructures 122 and dielectric structures 1717. As shown in FIG. 17, dielectric structures 1717 can remain between nanostructures 122 and gate structures 120. In some embodiments, dielectric structures 1717 may reduce the gate control of gate structures 120.

In some embodiments, as shown in FIG. 18, a portion of first dielectric layer 817 on S/D structures 110 may remain after the removal process of first dielectric layer 817 in operation 350 to form dielectric structures 1817. In some embodiments, dielectric structures 1817 and first dielectric layer 817 can include the same dielectric material. In some embodiments, dielectric structures 1817 and bottom isolation layer 117 can include different dielectric materials. In some embodiments, as shown in FIG. 18, dielectric structures 1817 can remain between S/D structures 110 and bottom isolation layer 117. In some embodiments, dielectric structures 1817 may not affect the device performance of semiconductor device 100.

Various embodiments in the present disclosure provide methods for forming conformal S/D structures in contact with convex inner spacers in semiconductor device 100. In some embodiments, semiconductor device 100 can include a stack of nanostructures 122 on a substrate 104. Gate structures 120 can wrap around the stack of nanostructures 122. S/D structures 110 can be disposed adjacent to gate structures 120 and in contact with the stack of nanostructures 122. Inner spacers 121 can be disposed between gate structures 120 and S/D structures 110. Bottom isolation layer 117 can be disposed between S/D structures 110 and substrate 104. In some embodiments, inner spacers 121 and bottom isolation layer 117 can include the same dielectric material. In some embodiments, inner spacers 121 can have a convex surface extending into S/D structures 110. In some embodiments, S/D structures 110 can be conformally formed on end portions of the stack of nanostructures 122. With the conformal S/D structures 110 in contact with the convex surface of inner spacers 121, the dislocation defects in the S/D structures 110 can be reduced, resistance of S/D structures 110 can be reduced, and the device performance of semiconductor device 100 can be improved. Additionally, bottom isolation layer 117 can reduce the leakage current of semiconductor device 100 and further improve the device performance. Moreover, inner spacers 121 and bottom isolation layer 117 can be formed in the same process to reduce manufacturing cost.

In some embodiments, a semiconductor structure includes a channel structure on a substrate, a gate structure wrapped around the channel structure, a S/D structure on the substrate and in contact with the channel structure, and an inner spacer between the gate structure and the S/D structure. A portion of the inner spacer extends into the S/D structure.

In some embodiments, a semiconductor device includes a stack of nanostructures on a substrate, a gate structure surrounding the stack of nanostructures, a S/D structure adjacent to the gate structure and in contact with the stack of nanostructures, and an inner spacer between the gate structure and the S/D structure. The inner spacer has a convex surface in contact with the S/D structure.

In some embodiments, a method includes forming first and second sets of nanostructures on a substrate. The first and second sets of nanostructures are stacked in an alternate configuration. The method further includes removing the second set of nanostructures to form an opening, forming a first dielectric layer in the opening and between the first set of nanostructures, forming a S/D structure on the first set of nanostructures and in contact with the first dielectric layer, replacing the first dielectric layer with a second dielectric layer, and forming a gate structure surrounding the first set of nanostructures. The gate structure is in contact with the second dielectric layer.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a channel structure on a substrate;
a gate structure wrapped around the channel structure;
a source/drain (S/D) structure on the substrate and in contact with the channel structure; and
an inner spacer between the gate structure and the S/D structure, wherein the inner spacer has a convex surface extending into the S/D structure.

2. The semiconductor structure of claim 1, further comprising an isolation layer on the substrate and in contact with the gate structure, wherein the S/D structure is on a top surface of the isolation layer.

3. The semiconductor structure of claim 2, wherein bottom surfaces of the gate structure and the isolation layer are substantially on a same level, and wherein the top surface of the isolation layer is below a bottom surface of the channel structure.

4. The semiconductor structure of claim 2, wherein a ratio of a thickness of the isolation layer to a thickness of the channel structure ranges from about 0.2 to about 0.8.

5. The semiconductor structure of claim 2, wherein the isolation layer and the inner spacer comprises a same dielectric material.

6. The semiconductor structure of claim 2, wherein the isolation layer comprises silicon oxide, silicon nitride, silicon carbide, silicon carbonitride, silicon oxynitride, silicon oxycarbonitride, or a combination thereof.

7. The semiconductor structure of claim 2, further comprising a dielectric structure between the isolation layer and the S/D structure, wherein the dielectric structure and the isolation layer comprise different dielectric materials.

8. The semiconductor structure of claim 2, further comprising a dielectric structure between the channel structure and the gate structure, wherein the dielectric structure and the isolation layer comprise different dielectric materials.

9. The semiconductor structure of claim 1, wherein the inner spacer is conformal on a concave surface of the S/D structure.

10. The semiconductor structure of claim 1, wherein the gate structure on the channel structure has an ellipse profile.

11. A method, comprising:
forming a plurality of nanostructures on a substrate;
forming an opening between the plurality of nanostructures;
forming a dielectric layer on the substrate and in the opening between the plurality of nanostructures;
forming a source/drain (S/D) structure on the substrate and adjacent to the plurality of nanostructures;
replacing the dielectric layer between the plurality of nanostructures with an inner spacer after forming the S/D structure; and
forming a gate structure surrounding the plurality of nanostructures, wherein the inner spacer is between the gate structure and the S/D structure.

12. The method of claim 11, further comprising:
removing the dielectric layer between the substrate and the S/D structure; and
forming an isolation layer between the substrate and the S/D structure, wherein the isolation layer and the inner spacer comprise a same dielectric material.

13. The method of claim 11, wherein replacing the dielectric layer with the inner spacer comprises:
removing the dielectric layer between the plurality of nanostructures;
conformally depositing a dielectric material on the plurality of nanostructures and the S/D structure; and
removing a portion of the dielectric material on the plurality of nanostructures to expose the plurality of nanostructures.

14. The method of claim 11, wherein forming the dielectric layer comprises:
depositing a dielectric material on the substrate and on the plurality of nanostructures; and
removing a portion of the dielectric material to expose end portions of the plurality of nanostructures.

15. The method of claim 11, wherein replacing the dielectric layer between the nanostructures with the inner spacer comprises forming an inner spacer with a convex surface on a concave surface of the S/D structure.

16. A method, comprising:
forming first and second sets of nanostructures on a substrate, wherein the first and second sets of nanostructures are stacked in an alternate configuration;
recessing the first and second sets of nanostructures to form an opening;
removing the second set of nanostructures through the opening to laterally extend the opening between the first set of nanostructures;
forming a first dielectric layer in the opening and between the first set of nanostructures;
forming a source/drain (S/D) structure on the first set of nanostructures;
replacing the first dielectric layer with a second dielectric layer; and
forming a gate structure surrounding the first set of nanostructures, wherein the second dielectric layer is between the gate structure and the S/D structure.

17. The method of claim 16, wherein replacing the first dielectric layer with the second dielectric layer comprises:
removing the first dielectric layer between the first set of nanostructures and between the S/D structure and the substrate;
depositing a dielectric material on the first set of nanostructures and between the S/D structure and the substrate; and
removing a portion of the dielectric material between the first set of nanostructures.

18. The method of claim 16, wherein forming the first dielectric layer comprises:
depositing a dielectric material on the substrate and the first set of nanostructures; and
removing a portion of the dielectric material to expose end portions of the first set of nanostructures.

19. The method of claim 16, wherein replacing the first dielectric layer with the second dielectric layer comprises forming an inner spacer with a convex surface extending into the S/D structure.

20. The method of claim 16, wherein replacing the first dielectric layer with the second dielectric layer comprises forming the second dielectric layer between the substrate and the S/D structure.
